(19) United States
(12) Patent Application Publication
(10) Pub. No.: US 2003/0235045 A1
(43) Pub. Date: Dec. 25, 2003

(54) CPU carrier unit

(76) Inventor: Cheng-Mao Chen, Taipei (TW)

Correspondence Address: RABIN & CHAMPAGNE, P.C., Suite 500, 1101 14th Street, N.W., Washington, DC, 20005, US

(21) Appl. No.: 10/176,617

(22) Filed: Jun. 24, 2002

(51) Int. Cl. H05K 7/14; H05K 7/18

(52) U.S. Cl. 361/801

(57) ABSTRACT

A CPU carrier compatible with high density multiple pins is used to enhance the contact between conductive terminals and CPU connector pins. On bottom of a top cover of CPU carrier is a formation of a space that is somewhat recessed and elevated. On a bottom side of each pinhole of the top cover is a formation of vertically extended auxiliary arm with a length no more than the height of said space. On a top of a conductive terminal that is inserted an insert hole of the CPU carrier unit and corresponding to the auxiliary of the top cover, is a horizontal extension of arched flexible clip. When the CPU is inserted, the flexible clip and the pin can be contacted firmly to avoid vibration, impact, and some problems caused by flexible fatigue, to enhance electrical conductivity between the CPU pin and conductive terminal and to enhance product quality.

### BACKGROUND OF THE INVENTION

(a) Field of the Invention

A structural improvement of CPU carrier unit, wherein on a bottom of a top cover of CPU carrier is a formation of a space that is somewhat recessed and elevated, on a bottom side of each pin hole of the top cover is a formation of auxiliary arm that is inserted in a conductive terminal inside each insert hole of the CPU carrier, on a top corresponding to the side of each auxiliary arm on the top cover is a horizontal extension of a flexible clip, to the effect that when each conductive terminal is inserted in the insert hole, the lower half part of the flexible clip is extended into the insert hole, while its upper half part is exposed out of the top of the insert hole, thereby when the CPU is inserted in the top cover, each pin and each auxiliary arm are respectively located at two sides of the flexible clip of the conductive terminal, and when the CPU is moved into position with the top cover, the auxiliary arm pushes an end of the flexible clip toward the pin, enabling firm contact with the pin, thereby achieving electrical conductivity and effectively upgrading product quality.

(b) Description of the Prior Art

There is a trend toward the development of high density multiple pins in recent years for the insert units for CPU assembly. Such pin terminals for CPU insertion can satisfy requirements for high precision quality, and can have the feature of compact size that is readily applicable to portable computers and miniaturized personal computers. The CPU carrier units currently in use (such as mPGA 478B) has a structure that is assembled by hinge joining a top cover A and a base unit B. Please refer to FIGS. 1 through 6, wherein, on the top cover A is even distribution of a plurality of pinholes A1, and on a base unit B is also even distribution of a plurality of insert holes B1 corresponding to the pinholes A1. In each insert hole B1 is a conductive terminal C. Said conductive terminal is made of flexible metal plate that is punch pressed to form. As shown in FIG. 2, on a top and extended horizontally are double-sided or single-sided flexible clips C1 (double-sided arrangement in the present embodiment). On the bottom is a horizontal bottom plate C2. The conductive terminal C is assembled to the bottom unit A. The conductive terminal C is inserted in the insert hole B1. As shown in FIG. 3, the top edge of inserted conductive terminal C is approximately flush with the top of insert hole B1. When all conductive terminals C are inserted in corresponding insert holes B1, solder paste D and solder balls E are spread on the bottom of the bottom plate C2, then they are welded to a circuit board F in a surface adhesion process for electrical conductivity. Thereby, the whole CPU carrier is fixed onto the circuit board F. Besides, on one side of the base unit B is a snap arm B2. By turning the snap arm B2 from its vertical status to horizontal status and fixing it to a protruded block A2 on a side of the top cover A, the top cover A is displaced. When the CPU is installed on the CPU carrier unit, all its pins G penetrate all pinholes A1 on the top cover A, then through the flexible clip C1 of the conductive terminal C in respective insert hole B1. Please refer to FIGS. 3 and 4 simultaneously. The CPU pin G is located slightly to the rear of the conductive terminal C, without contacting the conductive terminal C. When you turn the snap arm B2 to a horizontal status and fix it to the protruded block A2 of the top cover A, the top cover A drives the CPU to move slightly forward, as shown in FIGS. 5 and 6. Then, the CPU pins G move to between two flexible clips C1 of the conductive terminal C, enabling electrical contact with the flexible clip C1, so while the CPU is fixed to the CPU carrier, it is in electrical contact with the circuit board F.

However, in such conventional structure, the entire conductive terminal C is made of a metal plate that is punched and bent to form. Due to its flexibility, the shape of a metal plate is not easily controlled during its punching and forming process. It will easily result in error of inconsistent intervals between flexible clips C1. Or in actual applications, because of frequent friction on pins G of the CPU due to their frequent travel between the flexible clips C1, the flexible clips C1 will be stretched repeatedly and result in flexible fatigue, and poor connection with the pins G. In addition, in case the computer is frequently carried around and subjected to frequent collisions (such as a portable computer), the vibration will worsen poor connection between the pins G and the conductive terminal C, resulting in failure to start the computer and to operate normally, and seriously affect product quality.

In view of the above, the inventor has devoted in active research, based on many years of experience in the research and development of computer related components, and after repeated conception, test production, tests, and revisions, has come up with the present invention, involving a space that is recessed on the bottom of the top cover of a CPU carrier unit. Extending from a bottom side of each pinhole is an auxiliary arm. Extending horizontally from a top of the conductive terminal is a flexible clip. When inserted in an insert hole on a CPU carrier unit, the lower half of the flexible clip is extended into the insert hole, while its upper half is exposed out of the top of the insert hole, so that when the CPU is inserted in the top cover, the pins and the auxiliary arms on the top cover are respectively located on two sides of the flexible clip of the conductive terminal. When the CPU is moved into position by the top cover, the auxiliary arm pushes the flexible clip corresponding to the conductive terminal towards the pin, enabling firm contact with the pins to achieve better electrical conductivity and avoid errors in production of conductive terminal, or flexible fatigue after use, or poor connection caused by vibration, and to effectively upgrade product quality.

### BRIEF DESCRIPTION OF DRAWINGS

FIG. 1 is a perspective view of a prior art of CPU carrier unit.

FIG. 2 is a perspective view of conductive terminal inside a conventional CPU carrier unit.

FIG. 3 is a section view of a conventional CPU carrier unit with the insertion of a CPU, but a top cover and CPU are not moved to their positions.

FIG. 4 is a section view taken along line A-A in FIG. 3 showing the positions of conductive terminal and CPU pin inside the insert hole.

FIG. 5 is a section view of a conventional CPU carrier unit with the insertion of a CPU, and a top cover and CPU are moved to their positions.

FIG. 6 is a section view taken along line B-B in FIG. 5 showing the positions of conductive terminal and CPU pin inside the insert hole.

FIG. 7 is a structural view of a bottom of the top cover of the invention (a bottom view).

FIG. 8 is a view of the conductive terminal in the invention.

FIG. 9 is a section view of the invention of CPU carrier with the insertion of CPU, but the top cover and CPU are not moved to position.

FIG. 10 is a section view taken along line C-C showing the positions of conductive terminal, auxiliary arm and CPU pin inside the insert hole.

FIG. 11 is a section view of the invention of CPU carrier with the insertion of CPU, and the top cover and CPU are moved to position.

FIG. 12 is a section view taken along line D-D showing the positions of conductive terminal, auxiliary arm and CPU pin inside the insert hole.

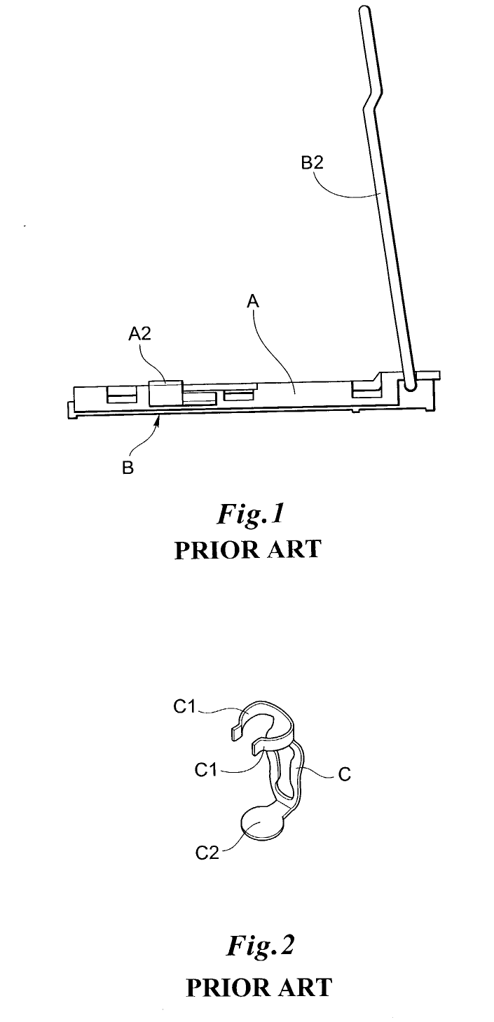

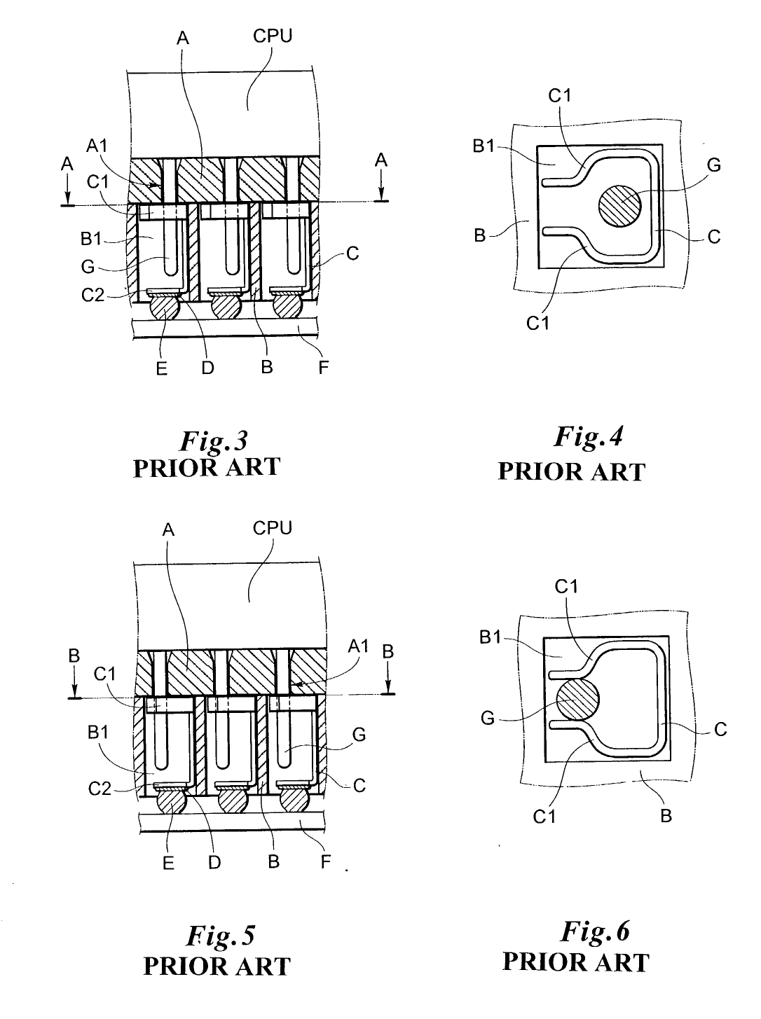

BRIEF DESCRIPTION OF NUMERALS

| | |
|---|---|
| 10 | top cover |
| 11 | space |
| 12 | pinhole |
| 13 | auxiliary arm |
| 20 | base |
| 21 | insert hole |
| 30 | conductive terminal |
| 31 | flexible clip |
| 40 | solder paste |
| 50 | solder ball |
| 60 | circuit board |
| 70 | CPU |
| 71 | pin |

### DETAILED DESCRIPTION OF PREFERRED EMBODIMENTS

For better understanding of the structural characteristics and anticipated performance of the present invention, please refer to the detailed description and drawings as follows.

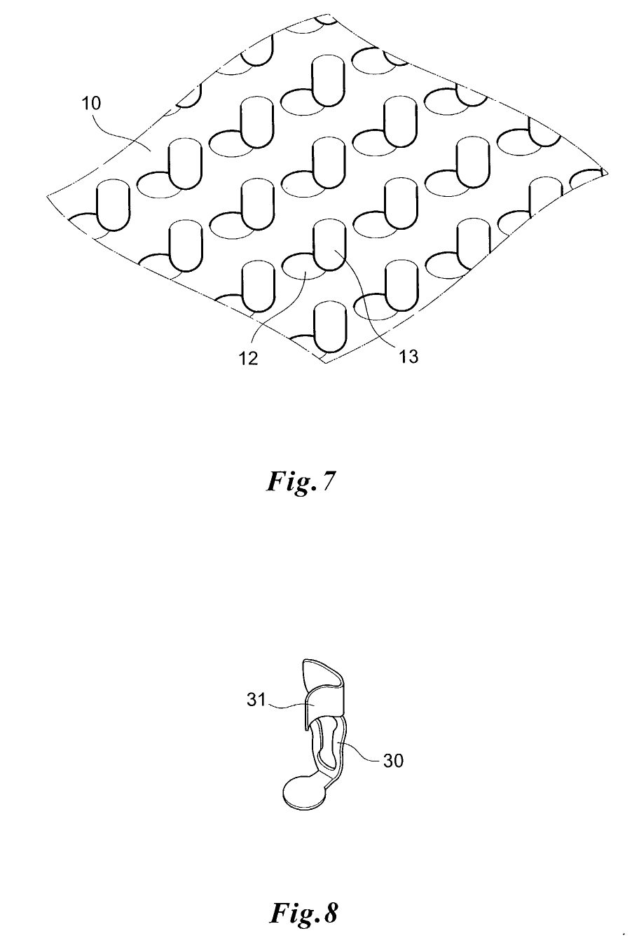

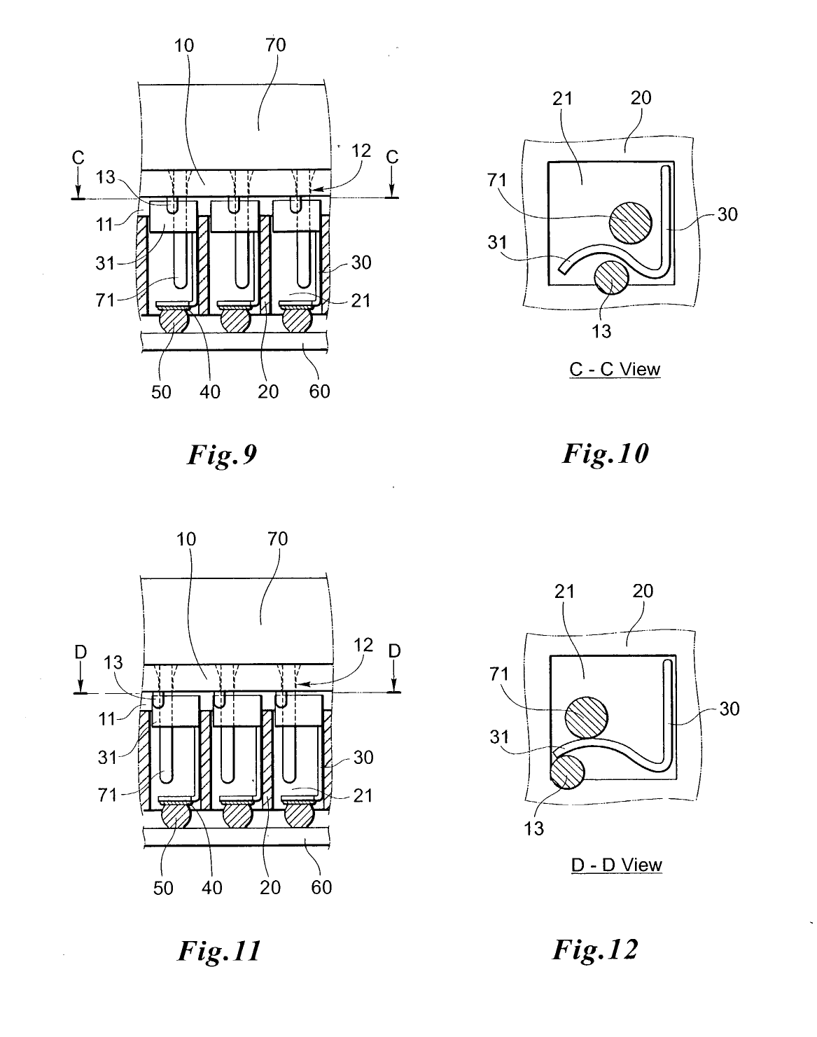

As shown in FIGS. 7 through 10, the present invention involves mainly a space 11 that is somewhat recessed and elevated on a bottom of a top cover 10 of CPU carrier unit, and an auxiliary arm 13 that is vertically extended from a specified position from the bottom side of each pinhole 12 of the top cover 10, length of each auxiliary arm 13 no longer than a height of inside the space 11 on the bottom of the top cover 10. At a top of a conductive terminal 30 that is inserted in each insert hole 21 of a base 20, on a side corresponding to the auxiliary arm 13 of the top cover 10, is a vertically extension of arched flexible clip 31. When each conductive terminal 30 is inserted in the insert hole 21and fixed by solder 40 and solder ball 50 to a circuit board 60, the lower half of the flexible clip 31 is extended in the insert hole 21 (thereby fixing the conductive terminal 30 in a transverse position inside the insert hole 21). The upper half of the flexible clip 31 is exposed out of a head of the insert hole 21 (inside the space 11 on the bottom of the top cover 10).

In such a structure, when a CPU 70 is inserted in the top of the top cover 10, each pin 71 running through each pin hole 12 of the top cover 10 and reaching into each corresponding insert hole 21 on the base 20, the pin 71 is located at a rear part inside the conductive terminal 30, without contacting the flexible clip 31. Meanwhile, when the top cover 10 is in this position (when a snap arm is somewhat in a vertical status), the auxiliary arm 13 extending from a side of each pinhole 12 is located at the outside of the flexible clip 31 of the conductive terminal 30 (slightly to the front of the pin 71), so the pin 71 and the auxiliary arm 13 are respectively located at two sides of the flexible clip 31. When the snap arm of the base 20 is turned to a level status and fixed, it brings the top cover 10 along with the CPU 70 to move into position, as shown in FIGS. 11 and 12, each auxiliary arm 13 and pin 70 is pulled and moved to a position somewhat ahead of the conductive terminal 30 shown in the drawing. Then, the auxiliary arm 13 serves to push an end of the flexible clip 31 of the conductive terminal 30 to move towards the pin 71, thereby the flexible clip 31 is forced into firm and solid contact with the pin 71. Therefore the above structural design is capable of preventing error in measurement and configuration when the conductive terminal 30 is pressed to form, or flexible fatigue from frequent use. Due to the tight contact, it will resist outside impact and vibration, and ensure consistent electrical contact. Due to loosened allowance for the production of conductive terminal 30, it made production quicker and easier, and higher satisfactory rate of products, thereby effectively enhancing the quality of finished computer products, and significantly increase their market competitiveness.

With sophisticated structural design, the present invention will effectively improve on the shortcoming of poor connection between CPU connector pins and the conductive terminals that are inserted in a conventional CPU carrier. By means of the auxiliary arms installed on the sides of the pinholes, and design of correct configuration of the flexible clip of the conductive terminal, the auxiliary arms serve to push the flexible clip into firm contact with CPU pins, enhancing better electrical conductivity and product durability, upgrading product quality and market competitiveness. With those advantages over the conventional similar products, the present invention has it inventive step, improvement and applicability. Therefore, this application is filed for a patent right. Your favorable consideration will be appreciated.

What is claimed is:

1. A structural improvement of CPU carrier unit, said CPU carrier unit comprising a top cover and a base that are hinged and assembled, wherein on a top cover unit and a base unit are evenly distributed a plurality of pinholes and insert holes, to a side of the base being hinged a snap arm serving to cause dislocation to the top cover, characterized in that:
On a bottom of the top cover is a recessed formation of a space, extending vertically from a specified position from a bottom side of each pinhole of the top cover being an auxiliary arm, length of each auxiliary arm no more than a height of the space on the bottom of the top cover, serving to accommodate the insertion of conductive terminal in each insert hole on the base, extending horizontally from a top of the top cover and corresponding to a same side of the auxiliary arm of the top cover being an arched flexible clip, when the conductive terminal is inserted and fixed in each insert hole, a lower half part of the flexible clip is extended in the insert hole, while an upper half of the flexible clip is exposed out of the top of the insert hole; when a CPU is inserted to the top of the top cover, and each pin penetrating through the pinhole of the top cover and reaching into the insert hole on the base, the pinhole and auxiliary arm are respectively located at two sides of the flexible clip of the conductive terminal, when the top cover and CPU are moved into position, the auxiliary arm pushes an end of the flexible clip towards a pin, thereby enabling firm and solid electrical contact between the flexible clip and the pin.
